(19) United States
(12) Patent Application Publication
(10) Pub. No.: US 2026/0157134 A1
(43) Pub. Date: Jun. 4, 2026

(54) SEMICONDUCTOR PACKAGE AND METHOD FOR FORMING THE SAME

(71) Applicant: Taiwan Semiconductor Manufacturing Co., Ltd., Hsinchu (TW)

(72) Inventors: Meng-Che Tu, Hsinchu (TW); Po-Han Wang, Hsinchu (TW); Hung-Jui Kuo, Hsinchu (TW)

(21) Appl. No.: 19/184,569

(22) Filed: Apr. 21, 2025

Related U.S. Application Data
(60) Provisional application No. 63/727,455, filed on Dec. 3, 2024.

(51) Int. Cl. H01L 23/00; H01L 21/56; H01L 21/78; H01L 23/31; H01L 23/544; H01L 23/58; H01L 25/00; H01L 25/11

(52) U.S. Cl. CPC H10P 54/00; H10W 42/00; H10W 46/00; H10W 70/09; H10W 74/01; H10W 74/121; H10W 90/00; H10W 46/301; H10W 70/6528; H10W 74/15; H10W 90/22; H10W 90/722; H10W 90/724; H10W 90/734

(57) ABSTRACT

In an embodiment, a method includes forming an interconnect structure including a plurality of die regions separated by scribe lines, at least one die region of the plurality of die regions including a semiconductor substrate and a routing structure on the semiconductor substrate, the routing structure including an alignment mark, the alignment mark being adjacent to the scribe lines. The method includes forming a passivation layer over the routing structure. The method includes removing a portion of the passivation layer to expose the alignment mark. The method includes performing a singulation process to separate the interconnect structure into individual dies.

### PRIORITY CLAIM AND CROSS-REFERENCE

This application claims the benefit of U.S. Provisional Application No. 63/727,455, filed on Dec. 3, 2024, which application is hereby incorporated herein by reference.

### BACKGROUND

The semiconductor industry has experienced rapid growth due to ongoing improvements in the integration density of a variety of electronic components (e.g., transistors, diodes, resistors, capacitors, etc.). For the most part, improvement in integration density has resulted from iterative reduction of minimum feature size, which allows more components to be integrated into a given area. As the demand for shrinking electronic devices has grown, a need for smaller and more creative packaging techniques of semiconductor dies has emerged.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A, 1B, 2A, 2B, 2C, 3A, 3B, 4, 5A, 5B, and 5C are cross-sectional views and to views of intermediate stages in the manufacturing of interconnect structures, in accordance with some embodiments.

FIGS. 6-7, 8A, 8B, and 9-15 are cross-sectional views of intermediate stages in the manufacturing of a semiconductor package, in accordance with some embodiments.

FIGS. 16A, 16B, and 17 are cross-sectional views of intermediate stages in the manufacturing of a semiconductor package, in accordance with some embodiments.

FIGS. 18A, 18B, and 19 are cross-sectional views of intermediate stages in the manufacturing of a semiconductor package, in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The semiconductor industry continually strives to improve the performance, reliability, and cost-effectiveness of integrated circuit packages. One important aspect of semiconductor packaging is the alignment of components during the assembly process. Accurate alignment is essential for ensuring proper electrical connections and overall package functionality. However, as semiconductor devices become smaller and more complex, achieving precise alignment becomes increasingly challenging.

A particular problem arises in the singulation of dies, such as interconnect dies (may also be referred to as local silicon interconnect (LSI) dies). During the singulation process, where individual dies are separated from a wafer, the passivation layer at the cutting edge of the die may be damaged or deformed. This damage can affect the clarity of alignment marks used for positioning the die during subsequent packaging steps. As a result, the alignment process becomes less reliable, leading to increased failure rates and reduced manufacturing yields.

The present disclosure addresses this challenge by introducing an approach to protecting and preserving alignment marks on the dies. In some embodiments, the alignment mark is not covered by the passivation layer that typically protects the die surface. Instead, the alignment mark may be exposed through an opening in the passivation layer. This exposure prevents the alignment mark from being affected by any deformation or damage to the passivation layer during the singulation process.

To further protect the exposed alignment mark, some embodiments include an insulation layer formed over the alignment mark. This insulation layer may be composed of a material different from the passivation layer, such as benzocyclobutene (BCB), polyimide (PI), or polybenzoxazole (PBO). The use of a different material allows for tailored protection of the alignment mark while maintaining its visibility for alignment purposes.

The disclosed approach offers several advantages in semiconductor packaging. By preserving the clarity and integrity of the alignment mark, the accuracy of die placement during the package-on-package process is significantly improved. This enhanced alignment precision leads to better electrical connections, reduced failure rates, and increased overall package reliability. Additionally, the improved alignment process may allow for tighter manufacturing tolerances, potentially enabling further miniaturization of semiconductor packages.

Furthermore, the disclosed method is compatible with existing semiconductor manufacturing processes and can be readily integrated into current production lines. This compatibility ensures that the benefits of improved alignment can be realized without requiring substantial changes to established manufacturing workflows or equipment.

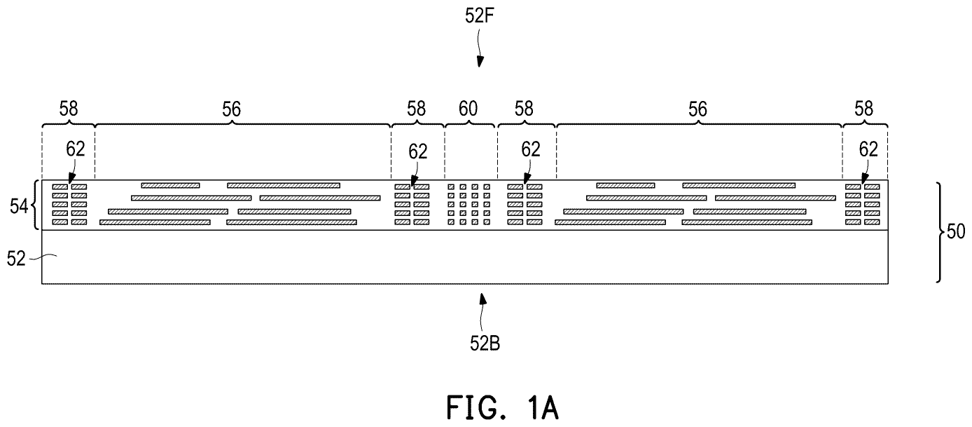

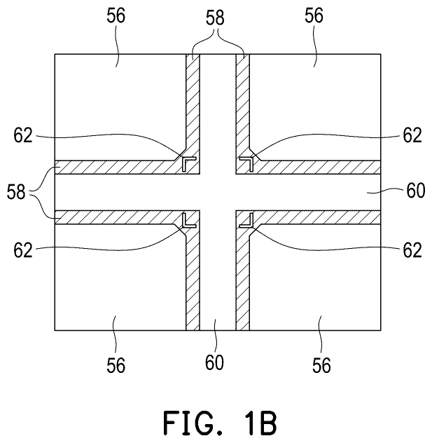

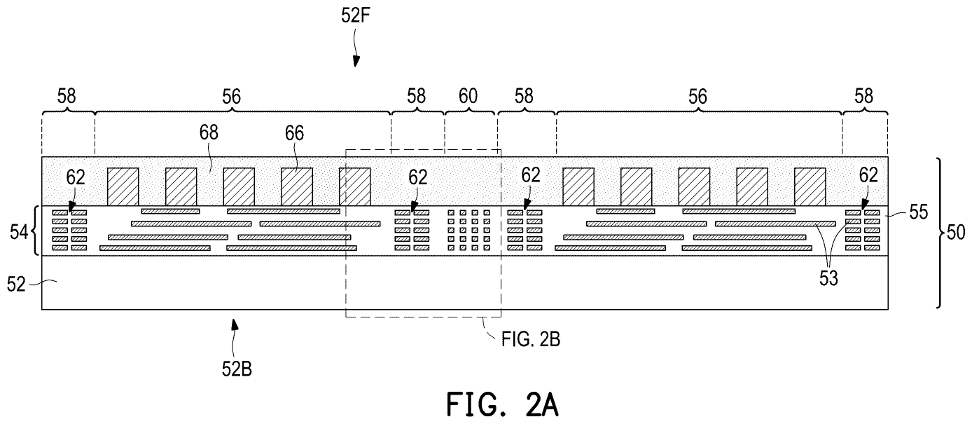

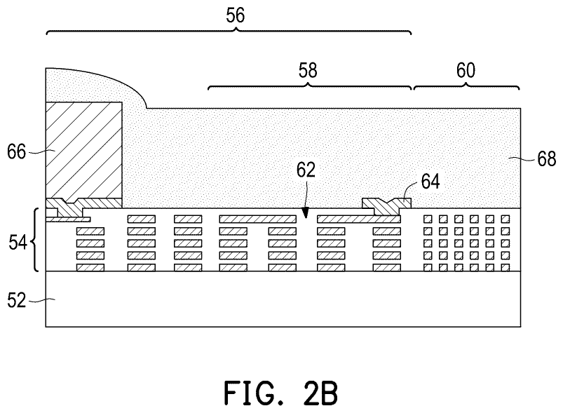

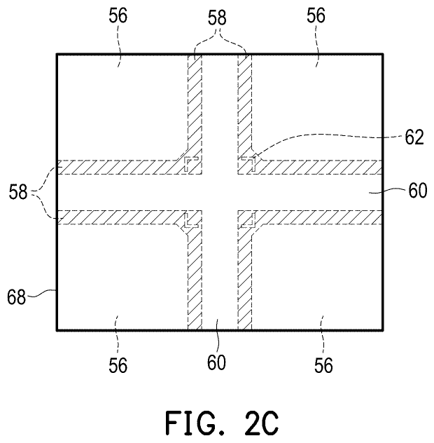

FIGS. 1A, 1B, 2A, 2B, 2C, 3A, 3B, 4, 5A, 5B, and 5C illustrate cross-section views and plan views of intermediate stages in the manufacturing of interconnect structures, in accordance with some embodiments. FIGS. 1A, 2A, and 5A illustrate cross-sectional views of intermediate stages in the manufacturing of interconnect structures. FIGS. 1B, 2C, 3B, and 5C illustrate plan views of intermediate stages in the manufacturing of interconnect structures. FIGS. 2B, 3A, 4, and 5B illustrate detailed cross-sectional views of intermediate stages in the manufacturing of interconnect structures.

In FIGS. 1A and 1B, an interconnect structure 50 is illustrated at an intermediate stage of processing. The interconnect structure 50 includes a semiconductor substrate 52 having a front side 52F and a backside 52B. A routing structure 54 is formed on the front side 52F of the semiconductor substrate 52. The routing structure 54 may contain various interconnect patterns distributed across the interconnect structure 50. The interconnect structure 50 may be a wafer. The interconnect structure 50 as illustrated in FIGS. 1A and 1B can be obtained or formed.

The interconnect structure 50 is divided into multiple die areas 56, as shown in FIG. 1B. Each die area 56 may be surrounded by a seal ring structure 58. The seal ring structure 58 is a wall-like structure that surrounds the die area 56 of the routing structure 54. The seal ring structures 58 may provide protection against moisture ingress and mechanical stress for the individual die areas 56. Between adjacent die areas 56, scribe lines 60 may be formed. These scribe lines 60 may define the boundaries where the interconnect structure 50 will be separated into individual dies during subsequent processing steps.

The seal ring structure 58 is disposed within the dielectric structure of the interconnect structure 50. It comprises a plurality of conductive lines and conductive vias arranged in a manner that forms a continuous barrier around the periphery of each die area 56. This arrangement helps to prevent moisture and contaminants from penetrating into the active regions of the die. The conductive lines and vias of the seal ring structure 58 may be formed during the same processing steps used to create the interconnect layers within the die area 56, allowing for efficient integration into the manufacturing process.

In some embodiments, at least one of the conductive vias in the seal ring structure 58 is formed of a material including copper at an atomic percentage greater than 80%. This high copper content helps to ensure the integrity of the seal ring structure. In some embodiments, the copper content may be even higher, with at least one of the conductive vias formed of a material including copper at an atomic percentage greater than 90%. This increased copper concentration may further enhance the performance and reliability of the seal ring structure.

The scribe lines 60 are regions between adjacent die areas 56 that are designed to be cut or broken during the separation of individual dies. The width of the scribe lines 60 may be determined based on factors such as the cutting method to be used, the desired final die size, and the need to accommodate any potential damage from the singulation process.

In some cases, the scribe lines 60 may contain test structures that are used during the manufacturing and packaging processes. These features can help with quality control; however, these structures are typically destroyed during the singulation process.

In some embodiments, the interconnect structure 50 may be an interposer and may not include active devices therein, although the interposer may include passive devices in some cases. In some embodiments, the interconnect structure 50 may include active devices (e.g., transistors or memory devices) formed in and/or on the front surface of the semiconductor substrate 52 (e.g., a surface at the front side 52F of semiconductor substrate 52). The semiconductor substrate 52 may be a bulk semiconductor substrate, a semiconductor-on-insulator (SOI) substrate, a multi-layered semiconductor substrate, or the like in some implementations. The semiconductor substrate 52 may include a semiconductor material, such as silicon; germanium; a compound semiconductor including silicon carbide, gallium arsenide, gallium phosphide, indium phosphide, indium arsenide, and/or indium antimonide; an alloy semiconductor including silicon-germanium, gallium arsenide phosphide, aluminum indium arsenide, aluminum gallium arsenide, gallium indium arsenide, gallium indium phosphide, and/or gallium indium arsenide phosphide; or combinations thereof in some cases. Other substrates, such as multi-layered or gradient substrates, may also be used in some embodiments.

Alignment marks 62 are positioned in the seal ring structures 58 and near the scribe lines 60, as illustrated in both FIG. 1A and FIG. 1B. The alignment marks 62 may be formed at multiple locations along the periphery of the die areas 56, with each alignment mark 62 positioned between adjacent seal ring structures 58. In some cases, the alignment marks 62 may be hollow patterns, which can enhance their visibility during alignment processes. In some embodiments, the alignment marks are hollow square patterns (see, e.g., FIG. 1B), but other alignment mark designs are within the scope of this disclosure, such as a cross-hair pattern, a box-in-box pattern, or the like.

The routing structure 54 disposed at the front side 52F of the semiconductor substrate 52 may include multiple layers of interconnect patterns. These interconnect patterns may facilitate electrical connections between various components within each die area 56 and may also provide connections to external devices.

The routing structure 54 comprises multiple layers of interconnect patterns (may be referred to as interconnect layers) that facilitate electrical connections within the device. These interconnect patterns include metallization patterns 53 and dielectric layers 55. The metallization patterns 53 may be formed of a conductive material, such as a metal, which may be copper, cobalt, aluminum, gold, combinations thereof, or the like and serve to carry electrical signals throughout the device. The dielectric layers 55 electrically isolate the metallization patterns 53 from each other and may include materials such as an oxide, a nitride, a carbide, a combination thereof, or the like. For example, the dielectric material may include silicon oxide, aluminum oxide, silicon nitride, silicon oxynitride, silicon carbide, silicon oxycarbide, silicon carbonitride, silicon oxycarbonitride, a combination thereof, or the like. In some embodiments, the dielectric layers 55 may include materials may such as a polymer like polybenzoxazole (PBO), polyimide, a benzocyclobutene (BCB) based polymer, or the like. The metallization patterns 53 may include conductive vias and/or conductive lines to interconnect components. In some embodiments, the routing structure 54 may be formed by a damascene process, such as a single damascene process, a dual damascene process, a combination thereof, or the like. In some embodiments, each of the metallization patterns 53 include metal lines disposed in a dielectric layer 55 and at least one of the metal lines includes a barrier layer (not separately illustrated) interfacing the dielectric layer 55 and a fill metal spaced apart from the dielectric layer 55 by the barrier layer. In some embodiments, an electrical conductivity of the barrier layer is less than an electrical conductivity of the fill metal of the metallization pattern 53. The barrier layer may include titanium, titanium nitride, tantalum, tantalum nitride, or the like while the fill metal may include copper, cobalt, aluminum, gold, or the like.

The alignment marks 62 formed in the routing structure 54 may be used in subsequent manufacturing processes. These alignment marks 62 may be used for positioning during die singulation, packaging, and integration with other components.

In FIGS. 2A, 2B, and 2C, conductive features 66 and a passivation layer 68 are formed over the routing structure 54. These conductive features 66 may include bond pads, redistribution layers, or other structures that facilitate electrical connections to external devices or packaging components. The conductive features 66 may be composed of materials similar to those used in the metallization patterns 53. In some embodiments, the conductive features 66 may be conductive pillars, conductive pads, or similar structures. The conductive features 66 can be formed of a metal, such as copper, aluminum, an alloy thereof, or other suitable conductive materials. In some cases, the conductive features 66 may be formed by plating or other deposition techniques. The conductive features 66 may be copper pillars in some embodiments.

The passivation layer 68 may be formed over the routing structure 54 and cover the conductive features 66. The passivation layer 68 may serve to protect the underlying structures from environmental factors such as moisture and contaminants. In some cases, the passivation layer 68 may be a polymer material, such as a polyimide, PBO, BCB, a combination thereof, or the like, and which may be formed by CVD, coating, or any suitable techniques. Alternatively, the passivation layer 68 may be a molding compound, which may include epoxy-based resins with or without particle fillers, and may be formed by compression molding, transfer molding, or the like.

FIG. 2B provides a more detailed cross-sectional view of a portion of the interconnect structure 50. As illustrated in FIG. 2B, a pad layer 64 is formed on top of the routing structure 54. The conductive features 66 may be formed on the pad layer 64. Another portion of the pad layer 64 may be in the seal ring structure 58 area. In some embodiments, the pad layer 64 may be composed of materials such as aluminum, copper, or alloys thereof.

FIG. 2C illustrates a plan view of the layout of multiple die areas 56. Each die area 56 is surrounded by a seal ring structure 58, which provides mechanical strength and acts as a barrier against moisture and contaminants. Scribe lines 60 are visible between the die areas 56, defining the regions where the wafer will be cut to separate individual dies.

The alignment marks 62 are positioned at the intersections of the scribe lines 60. These alignment marks 62 help to ensure accurate positioning during subsequent manufacturing processes, such as die singulation and packaging. At this point in processing, the passivation layer 68 extends the alignment marks 62, but may be subsequently patterned to expose certain areas, such as the alignment marks 62 or portions of the conductive features 66.

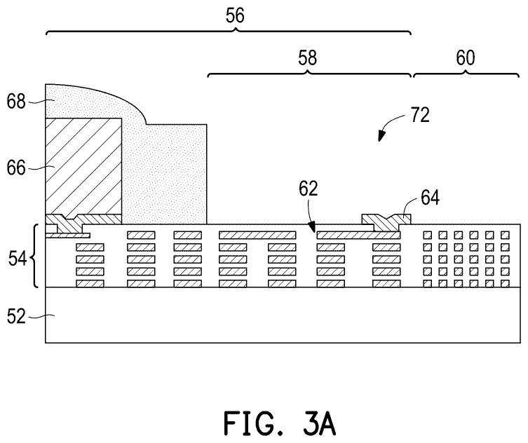

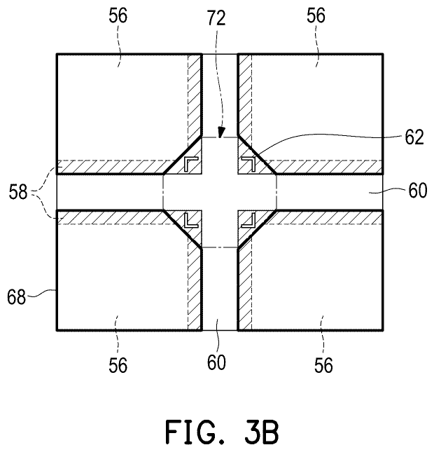

In FIGS. 3A and 3B, the passivation layer is patterned to form an opening 72 to expose the alignment mark 62. This patterning process creates an opening 72 in the passivation layer 68, directly above the alignment mark 62. Optionally, the opening 72 may also be disposed directly above the scribe lines 60. In some embodiments, the process of removing the portion of the passivation layer 68 may be performed using a photolithography process. In some cases, this process may involve applying a photoresist layer over the passivation layer 68, exposing the photoresist through a mask pattern, developing the photoresist to create openings corresponding to the desired areas for removal, and then etching the exposed portions of the passivation layer 68.

FIG. 3B illustrates a plan view of the interconnect structure 50 after the alignment mark 62 and, optionally, the scribe lines 60 have been exposed. The opening 72 in the passivation layer 68 allows direct access to the alignment mark 62. The exposed alignment mark 62 is positioned at the intersection of the scribe lines 60, between the corners of adjacent die areas 56. In some embodiments, the opening 72 has an octagonal shape in a plan view, and corners of the opening 72 abutting the passivation layer 68 are slanted in the plan view. In embodiments where the scribe lines 60 are exposed, the opening 72 may have an octagonal shape that is provided by a geometric octagon merged with the cross-like shape of the intersecting, scribe lines 60.

Exposing the alignment mark 62 through the opening 72 in the passivation layer 68 may provide several benefits for subsequent manufacturing processes. The exposed alignment mark 62 may offer improved visibility and contrast for alignment equipment, leading to more accurate positioning during die singulation and packaging steps. Additionally, by removing the passivation layer 68 over the alignment mark 62, any potential distortion or damage to the passivation layer 68 during singulation may not affect the clarity of the alignment mark 62.

In some cases, the exposed alignment mark 62 may allow for more precise alignment during subsequent packaging processes, such as when placing the singulated die onto a carrier substrate or when aligning multiple dies in a package-on-package configuration. The improved alignment accuracy may contribute to better electrical connections and overall package reliability. Further, in embodiments where the scribe lines 60 are also exposed, subsequent singulation processes are not applied to the passivation layer 68. As a result, defects to the passivation layer (e.g., deformation) that are caused by the singulation process can be avoided.

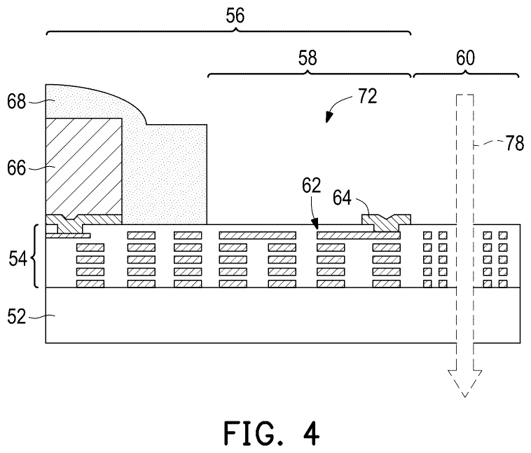

FIG. 4 illustrates a singulation process 78 to separate individual interconnect dies 50A from the interconnect structure 50. The singulation process 78 may be performed using a combination of laser grooving and blade sawing. In some cases, laser grooving may be used to create an initial groove along the scribe line 60. This initial groove may help guide the subsequent blade sawing process, potentially improving the accuracy of the die separation.

The blade sawing process may then be used to complete the separation of individual interconnect dies. During this process, a saw blade may cut through the remaining material along the scribe line 60, effectively separating the interconnect dies from one another.

By exposing the alignment mark 62 through the opening 72 in the passivation layer 68, the alignment mark 62 remains clearly visible even if the passivation layer 68 near the cutting edge becomes damaged or deformed during the singulation process 78. In embodiments where the scribe lines 60 are also exposed by the opening 72, the singulation process 78 is not applied to the passivation layer 68, damage to the passivation layer 68 (e.g., deformation) can be avoided, and clarity of the alignment mark 62 can be further improved. This approach helps maintain the accuracy of subsequent alignment steps in the packaging process.

In some cases, the combination of laser grooving and blade sawing in the singulation process 78 may help minimize damage to the passivation layer 68 and other structures near the cutting edge. This may further contribute to preserving the integrity and visibility of the alignment mark 62, potentially improving the overall alignment accuracy in subsequent manufacturing steps.

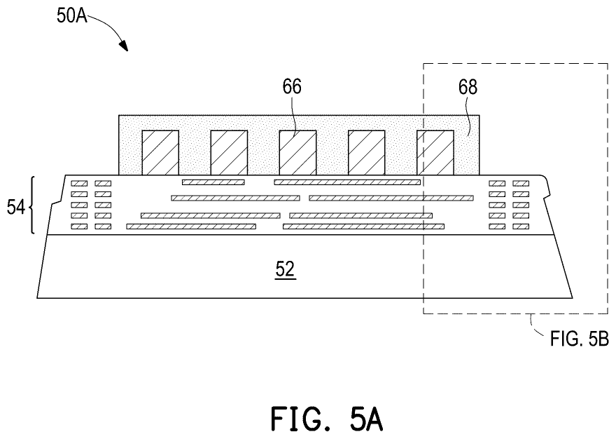

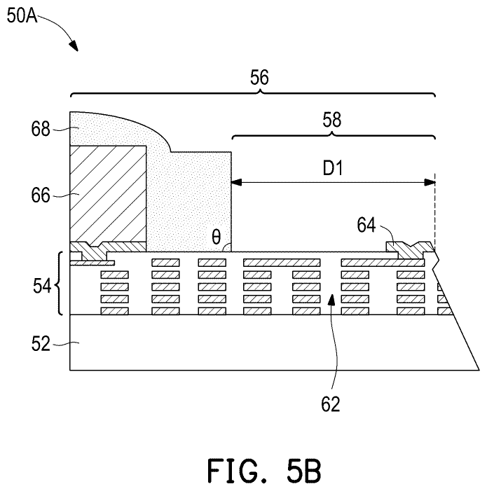

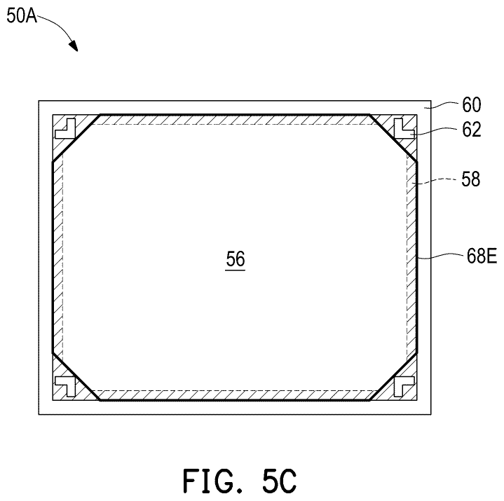

FIGS. 5A, 5B, and 5C illustrate the singulated interconnect die 50A. As clearly shown in FIG. 5B, the sidewalls of the interconnect die 50A (including sidewalls of the semiconductor substrate 52 and the routing structure 54) after singulation exhibit a non-planar and non-perpendicular profile relative to the major top surface (or major bottom surface) of the interconnect die 50A. This non-planar sidewall configuration is a characteristic resulting from the singulation process, particularly from the combination of laser grooving and blade sawing described previously.

After singulation, a distance D1 can be measured from a sidewall of the passivation layer 68 to a top of the sidewall of the interconnect die 50A, as indicated in FIG. 5B. In some embodiments, the distance D1 may be less than 20 microns. This dimensional characteristic represents the amount of die material extending beyond the passivation layer edge. Additionally, the sidewall of the passivation layer 68 forms an angle (theta) as measured from a top surface of the routing structure 54. In some embodiments, the angle theta is in a range from 70 degrees to 90 degrees, which creates an outwardly sloped profile at the edge of the passivation layer.

The non-planar sidewall configuration of interconnect die 50A includes varying slopes and may contain micro-irregularities that results from the singulation process. The sidewall profile may include multiple distinct regions with different degrees of roughness and inclination. The semiconductor substrate 52 region may exhibit one type of non-planar surface characteristic, while the routing structure 54 region may present a different non-planar profile due to the differing material compositions and their respective responses to the singulation process. In some embodiments, the sidewall of the routing structure 54 may have a different slope than the sidewall of the semiconductor substrate 52. For example, the particular embodiment illustrated in FIG. 5B, the slope of the sidewall of the routing structure has at least a portion with a smaller slope value than the slope of any portion of the sidewall of the semiconductor substrate 52.

Furthermore, the non-planar sidewall configuration may include micro-terracing or stepped features at interfaces between different material layers, particularly visible at the interface between the semiconductor substrate 52 and the routing structure 54. These micro-features are a result of the differential material removal rates during the singulation process. The degree of non-planarity may vary around the perimeter of the die, with corner regions potentially exhibiting more pronounced non-planar characteristics compared to the straight edge regions.

In contrast, the singulation process may not be applied to the passivation layer 68. For example, the passivation layer 68 in the scribe line regions 60 may be removed by photolithography and etching as described above. As a result, sidewalls of the passivation layer 68 may be substantially planar and may have a different surface roughness than the non-planar sidewalls of the substrate 52 and/or the routing structure 54.

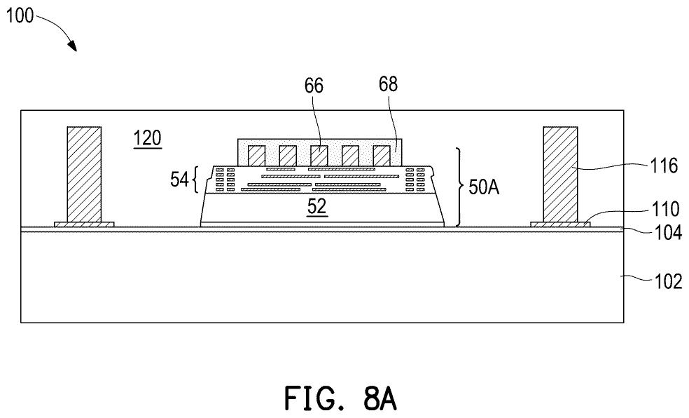

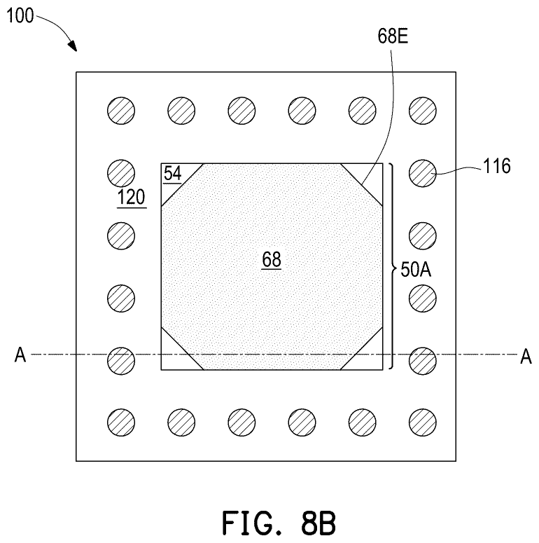

FIG. 5C illustrates a plan view of the interconnect die 50A. The die area 56 is surrounded by the seal ring structure 58. An alignment mark 62 is positioned at each corner of the die area 56. In some embodiments, a portion of the scribe line 60 remains at the edge of the interconnect die 50A. A passivation layer edge 68E extends along the perimeter of the die area 56, and in some embodiments, has an octagonal shape in the plan view (see FIG. 8B). The alignment marks 62 are positioned between the scribe line 60 and the passivation layer edge 68E at the corners of the interconnect die 50A.

The octagonal shape of the passivation layer edge 68E (see FIG. 8B) provides advantages over other patterns (e.g., rectangular or circular). This geometry improves stress distribution at the corners, reducing the likelihood of delamination or cracking during thermal cycling. The octagonal design may also provide improved alignment visibility by creating distinct reference points while maintaining structural integrity. Furthermore, the octagonal pattern helps minimize edge chipping during the singulation process by avoiding sharp 90-degree corners where stress concentrations can lead to material failure.

The alignment marks 62 in the interconnect die 50A may be exposed through openings in the passivation layer 68. This exposure may allow for improved visibility and accuracy during subsequent alignment processes. The exposed alignment marks 62 may be less susceptible to distortion or damage that could occur if they were covered by the passivation layer 68. The exposed alignment marks 62 may enable more precise positioning during packaging processes, potentially leading to improved electrical connections and overall package reliability.

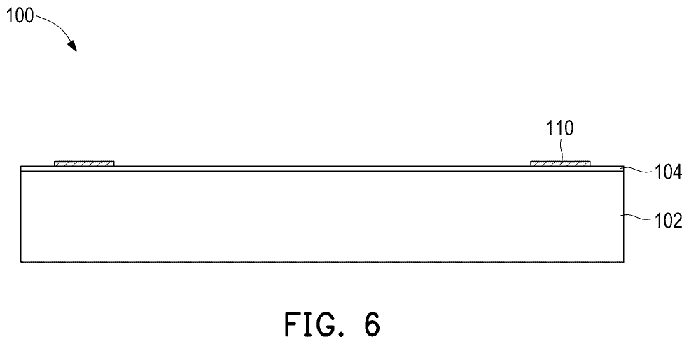

FIG. 6-15 illustrate cross-sectional views of intermediate stages in the manufacturing of a semiconductor package 100, in accordance with some embodiments.

FIG. 6 illustrates a cross-sectional view of a semiconductor package 100 during an intermediate stage of assembly. The semiconductor package 100 includes a carrier substrate 102 that serves as a base structure for subsequent processing steps. A release layer 104 is disposed on the carrier substrate 102, extending across the upper surface of the carrier substrate 102. The release layer 104 may facilitate the separation of the completed package from the carrier substrate 102 in later manufacturing stages.

The release layer 104 may be formed of a polymer-based material, which may be removed along with the carrier substrate 102 from the overlying structures that will be formed in subsequent steps. In some embodiments, the release layer 104 is an epoxy-based thermal-release material, which loses its adhesive property when heated, such as a light-to-heat-conversion (LTHC) release coating. In other embodiments, the release layer 104 may be an ultra-violet (UV) glue, which loses its adhesive property when exposed to UV lights. The release layer 104 may be dispensed as a liquid and cured, may be a laminate film laminated onto the carrier substrate 102, or may be the like.

A metallization pattern 110 is formed on the release layer 104. The metallization pattern 110 may include various conductive traces and pads that provide electrical connections within the semiconductor package 100. In some embodiments, the metallization pattern 110 may be formed using photolithography and etching processes to create the desired conductive patterns.

As an example to form the metallization pattern 110, a seed layer is formed over the release layer 104. In some embodiments, the seed layer is a metal layer, which may be a single layer or a composite layer comprising a plurality of sub-layers formed of different materials. In some embodiments, the seed layer comprises a titanium layer and a copper layer over the titanium layer. The seed layer may be formed using, for example, physical vapor deposition (PVD) or the like. A photoresist is then formed and patterned on the seed layer. The photoresist may be formed by spin coating or the like and may be exposed to light for patterning. The pattern of the photoresist corresponds to the metallization pattern 110. The patterning forms openings through the photoresist to expose the seed layer. A conductive material is formed in the openings of the photoresist and on the exposed portions of the seed layer. The conductive material may be formed by plating, such as electroplating or electroless plating, or the like. The conductive material may comprise a metal, like copper, titanium, tungsten, aluminum, or the like. Then, the photoresist and portions of the seed layer on which the conductive material is not formed are removed. The photoresist may be removed by an acceptable ashing or stripping process, such as using an oxygen plasma or the like. Once the photoresist is removed, exposed portions of the seed layer are removed, such as by using an acceptable etching process, such as by wet or dry etching. The remaining portions of the seed layer and conductive material form the metallization pattern 110.

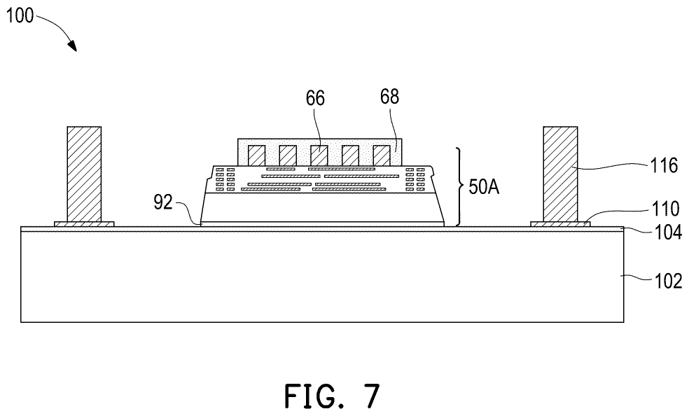

In FIG. 7, the interconnect die 50A is mounted on the carrier substrate 102. The interconnect die 50A may be derived from the previously described interconnect structure 50, which has undergone the singulation process to separate individual dies.

The interconnect die 50A includes the semiconductor substrate 52 with the routing structure 54 formed on the front side 52F. The conductive features 66 are positioned on the upper surface of the interconnect die 50A, and the passivation layer 68 covers these conductive features 66.

An adhesive film 92 may be used to secure the interconnect die 50A to the carrier substrate 102. The adhesive film 92 may provide a temporary bond that holds the interconnect die 50A in place during subsequent processing steps.

Through vias 116 are formed on either side of the interconnect die 50A. The through vias 116 extend vertically from the metallization pattern 110 on the release layer 104. In some embodiments, the through vias 116 may be formed by creating openings in the structure and filling these openings with a conductive material.

A photoresist is deposited over the carrier substrate 102 and patterned to expose at least a portion of the metallization pattern 110. The photoresist may be formed by spin coating or the like and may be exposed to light for patterning. The pattern of the photoresist corresponds to the through vias 116. A conductive material is formed in the openings of the photoresist and on the exposed portions of the metallization pattern 110. The conductive material may comprise a metal, like copper, titanium, tungsten, aluminum, or the like. In some embodiments, the conductive material may be formed by plating, such as electroplating or electroless plating, or the like, directly on the metallization pattern 110 without a seed layer. The photoresist may be removed after the through vias 116 are formed, by an acceptable ashing or stripping process, such as using an oxygen plasma or the like.

In FIGS. 8A and 8B an encapsulant 120 is formed to surround the interconnect die 50A and the through vias 116. FIG. 8B is a plan view along the line A-A in FIG. 8A. The encapsulant 120 may provide structural support and protection for the interconnect die 50A and other components within the semiconductor package 100. As illustrated in FIG. 8B, the footprint of the encapsulant 120 is greater than a footprint of the interconnect die 50A in a plan view. In this embodiment, the encapsulant covers the alignment mark 62 in the routing structure 54. In some embodiments, the alignment mark 62 is covered by an insulation layer before encapsulation.

The encapsulant 120 may be formed using a molding process. In some cases, a molding compound may be injected around the interconnect die 50A and the through vias 116. The molding compound may then be cured to form the solid encapsulant 120. The encapsulant 120 may extend laterally to encapsulate the sides of the interconnect die 50A and may also extend over the alignment mark 62.

The encapsulant 120 may be a molding compound, which may include a base material of a resin, an epoxy, or the like, and also include filler particles in the base material. The filler particles may be dielectric particles of SiO₂, Al₂O₃, or the like, and may have spherical shapes. Also, the spherical filler particles may have a plurality of different diameters. The encapsulant 120 may be applied by compression molding, transfer molding, or the like. For example, the encapsulant 120 may be applied in liquid or semi-liquid form and then subsequently cured. Other encapsulant materials, such as oxide gap fill materials, may be used in other embodiments.

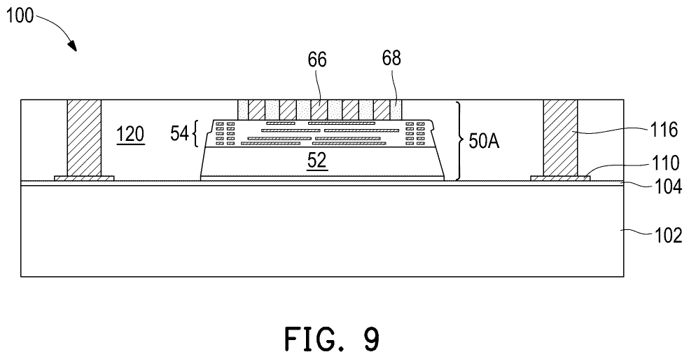

In FIG. 9 a planarization process may be performed on the upper surface of the encapsulant 120. This planarization process may ensure a flat surface for the formation of subsequent layers. The planarization process may also expose the top surfaces of the conductive features 66 and the through vias 116, allowing for electrical connections to be made in subsequent processing.

The planarization process may be, for example, a chemical-mechanical polish (CMP), a grinding process, or the like. Top surfaces of the through vias 116, the conductive features 66, the passivation layer 68, and the encapsulant 120 are substantially coplanar after the planarization process within process variations.

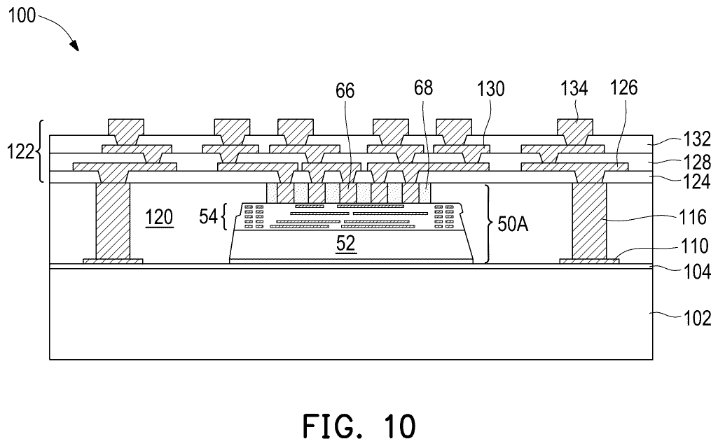

In FIG. 10 a front-side redistribution structure 122 is formed over the interconnect die 50A, the encapsulant 120, and the through vias 116. The front-side redistribution structure 122 may be formed over the encapsulant 120 and may be electrically connected to the conductive features 66 of the interconnect die 50A and the through vias 116.

The front-side redistribution structure 122 may include multiple layers of dielectric materials and conductive patterns. In some cases, the front-side redistribution structure 122 may include a dielectric layers 124, 128, and 132. These dielectric layers may provide insulation between conductive elements and may also serve as a foundation for building up the redistribution structure.

Metallization patterns 126 may be formed within or on the dielectric layer 124. Similarly, a metallization pattern 130 may be formed within or on the dielectric layer 128, and metallization patterns 134 may be formed within or on the dielectric layer 132. These metallization patterns may provide electrical routing paths within the front-side redistribution structure 122.

The front-side redistribution structure 122 is shown as an example of three dielectric layers and three layers of metallization patterns. More or fewer dielectric layers and metallization patterns may be formed in the front-side redistribution structure 122. If fewer dielectric layers and metallization patterns are to be formed, steps and processes discussed below may be omitted. If more dielectric layers and metallization patterns are to be formed, steps and processes discussed below may be repeated.

The metallization patterns 126, 130, and 134 may be formed using various deposition and patterning techniques. In some cases, these metallization patterns may be formed using processes such as sputtering, electroplating, or chemical vapor deposition, followed by photolithography and etching to create the desired patterns.

The formation of front-side redistribution structure 122 may include depositing the dielectric layer 124 on the top surfaces of the through vias 116, the encapsulant 120, and the conductive features 66. In some embodiments, the dielectric layer 124 is formed of a photosensitive material such as PBO, polyimide, benzocyclobutene (BCB), or the like, which may be patterned using a lithography mask. The dielectric layer 124 may be formed by spin coating, lamination, CVD, the like, or a combination thereof. The dielectric layer 124 is then patterned. The patterning forms openings exposing the conductive features 66 and the through vias 116. The patterning may be performed by an acceptable process, such as by exposing and developing the dielectric layer 124 to light or by etching using, for example, an anisotropic etch.

The metallization pattern 126 is then formed. The metallization pattern 126 includes conductive elements extending along the major surface of the dielectric layer 124 (e.g., a conductive line portion) and extending through the dielectric layer 124 (e.g., a conductive via portion) to physically and electrically coupled to the conductive features 66 and the through vias 116. As an example to form the metallization pattern 126, a seed layer is formed over the dielectric layer 124 and in the openings extending through the dielectric layer 124. In some embodiments, the seed layer is a metal layer, which may be a single layer or a composite layer comprising a plurality of sub-layers formed of different materials. In some embodiments, the seed layer comprises a titanium layer and a copper layer over the titanium layer. The seed layer may be formed using, for example, PVD or the like. A photoresist is then formed and patterned on the seed layer. The photoresist may be formed by spin coating or the like and may be exposed to light for patterning. The pattern of the photoresist corresponds to the metallization pattern 126. The patterning forms openings through the photoresist to expose the seed layer. A conductive material is then formed in the openings of the photoresist and on the exposed portions of the seed layer. The conductive material may be formed by plating, such as electroplating or electroless plating, or the like. The conductive material may comprise a metal, like copper, titanium, tungsten, aluminum, alloy thereof, or the like. In some embodiments, a liner may be formed in the openings before the conductive material. The liner (not separately illustrated), such as a diffusion barrier layer, an adhesion layer, or the like, and the conductive material are formed in the openings. The liner may include titanium, titanium nitride, tantalum, tantalum nitride, or the like. The photoresist and portions of the seed layer on which the conductive material is not formed are removed. The photoresist may be removed by an acceptable ashing or stripping process, such as using an oxygen plasma or the like. Once the photoresist is removed, exposed portions of the seed layer are removed, such as by using an acceptable etching process, such as by wet or dry etching. The combination of the conductive material and remaining portions of the seed layer form the metallization pattern 126.

Next, the dielectric layer 128 is deposited on the metallization pattern 126 and dielectric layer 124. The dielectric layer 128 may have a material similar to the dielectric layer 124, and may be formed in a manner similar. The metallization pattern 130 is then formed. The metallization pattern 130 includes portions on and extending along the major surface of the dielectric layer 128. The metallization pattern 130 further includes portions extending through the dielectric layer 128 to physically and electrically couple the metallization pattern 126. The metallization pattern 130 may be formed in a similar manner and of a similar material as the metallization pattern 126.

Next, the dielectric layer 132 is deposited on the metallization pattern 130 and dielectric layer 128. The dielectric layer 132 may have a material similar to the dielectric layer 124, and may be formed in a manner similar. The metallization pattern 134 is then formed. The metallization pattern 134 may be formed in a similar manner to the metallization pattern 134 and may include a similar material as the metallization pattern 126. The dielectric layer 132 is the topmost dielectric layer of the redistribution structure 122, and the metallization pattern 134 is the topmost metallization pattern for external connections, in accordance with some embodiments. The metallization pattern 134 may have via portions extending through the dielectric layer 132 to physically and electrically couple the metallization pattern 130. The metallization pattern 134 may electrically couple to the interconnect die 50A and/or the through vias 116.

The front-side redistribution structure 122 may allow for the redistribution of electrical connections from the interconnect die 50A to other locations on the surface of the semiconductor package 100. This redistribution may enable more flexible placement of external connections and may facilitate the integration of the semiconductor package 100 with other components or packages. In some embodiments, the metallization patterns of the redistribution structure 122 act as signal lines, power routing lines, and/or a ground routing lines for the package structure.

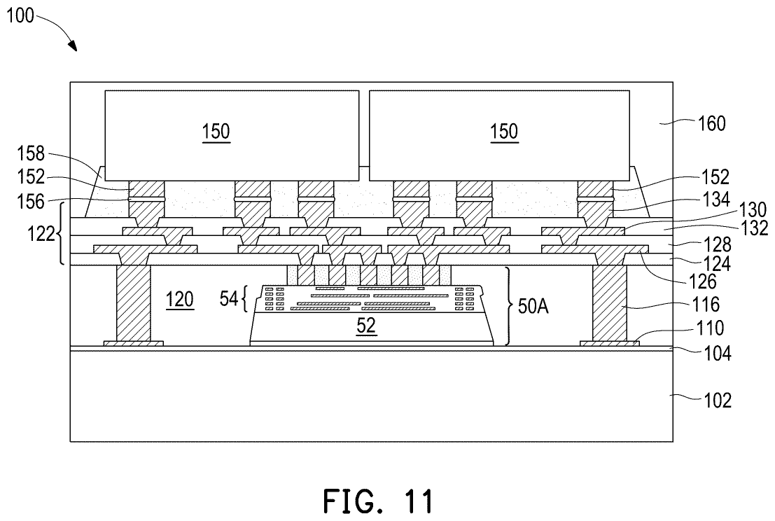

In FIG. 11 integrated circuit devices 150 are integrated into the package structure. The integrated circuit devices 150 are mounted on the front-side redistribution structure 122. In some embodiments, the integrated circuit devices 150 may be flip-chip devices, with active circuitry facing the redistribution structure 122. The integrated circuit devices 150 are electrically connected to the redistribution structure 122 through conductive connectors 156. These conductive connectors 156 may be solder balls, copper pillars, or other suitable conductive structures that provide electrical pathways between the integrated circuit devices 150 and the underlying redistribution structure 122.

External connectors 152 may be formed on the front-side redistribution structure 122. These external connectors 152 may provide additional electrical connections for the semiconductor package 100, allowing for communication with external devices or circuit boards.

The integrated circuit devices 150 may be placed on the front-side redistribution structure 122 using, e.g., a pick-and-place tool. The conductive connectors 156 may be formed of a reflowable conductive material, such as solder, and may further include other conductive materials such as copper, aluminum, gold, nickel, silver, palladium, tin, lead, the like, or a combination thereof. In some embodiments, the conductive connectors 156 are formed by initially forming a layer of solder through methods such as evaporation, electroplating, printing, solder transfer, ball placement, or the like. Attaching the integrated circuit devices 150 to the front-side redistribution structure 122 may include placing the integrated circuit devices 150 on the front-side redistribution structure 122 and reflowing the conductive connectors 156. The conductive connectors 156 form joints between corresponding metallization patterns 134 of the front-side redistribution structure 122 and the corresponding external connectors 152 of the integrated circuit devices 150, electrically connecting the integrated circuit devices 150 to the interconnect die 50A and/or the through vias 116.

An underfill 158 may be dispensed between the integrated circuit devices 150 and the front-side redistribution structure 122. The underfill 158 surrounds the conductive connectors 156, providing mechanical support and protection for these electrical connections. In some cases, the underfill 158 helps to distribute stress and protect against environmental factors such as moisture. The underfill 158 may be formed of an underfill material such as an epoxy, or the like. The underfill 158 may be formed by a capillary flow process after the integrated circuit devices 150 are attached to the front-side redistribution structure 122, or may be formed by a suitable deposition method before the integrated circuit devices 150 are attached to the front-side redistribution structure 122. The underfill 158 may be applied in liquid or semi-liquid form and then subsequently cured.

Further in FIG. 11, an encapsulant 160 is formed over the integrated circuit devices 150 and the front-side redistribution structure 122. The encapsulant 160 may provide additional protection for the integrated circuit devices 150 and other components of the semiconductor package 100. In some cases, the encapsulant 160 may be a molding compound that is applied using a molding process.

The encapsulant 160 encapsulates the integrated circuit devices 150 and the underfill 158. As such, the integrated circuit devices 150 are buried or covered by the encapsulant 160. The encapsulant 160 may be a molding compound, which may include a base material of a resin, an epoxy, or the like, and also include filler particles in the base material. The filler particles may be dielectric particles of SiO2, Al2O3, or the like, and may have spherical shapes. Also, the spherical filler particles may have a plurality of different diameters. The encapsulant 160 may be applied by compression molding, transfer molding, or the like. For example, the encapsulant 160 may be applied in liquid or semi-liquid form and then subsequently cured.

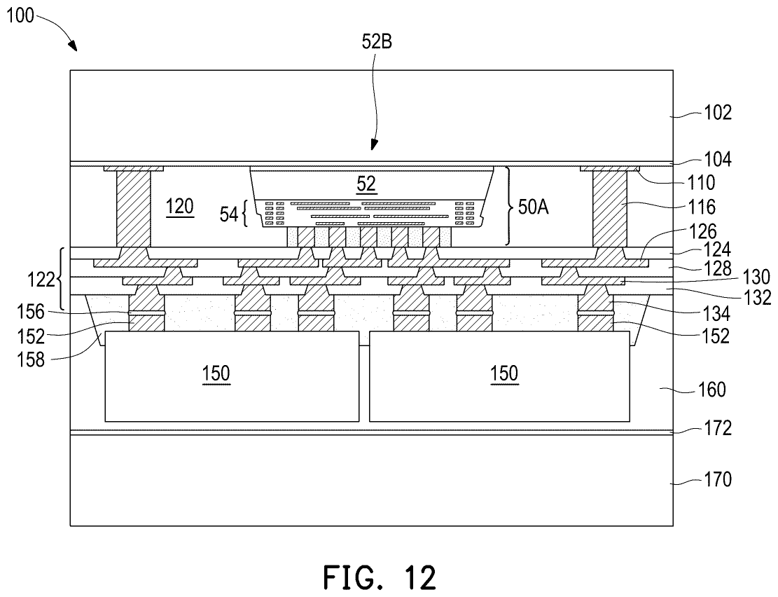

In FIG. 12, the semiconductor package 100 may be mounted on a second carrier substrate 170. A release layer 172 may be disposed between the semiconductor package 100 and the second carrier substrate 170. This configuration may allow for further processing steps or testing to be performed on the semiconductor package 100 before final separation from the second carrier substrate 170.

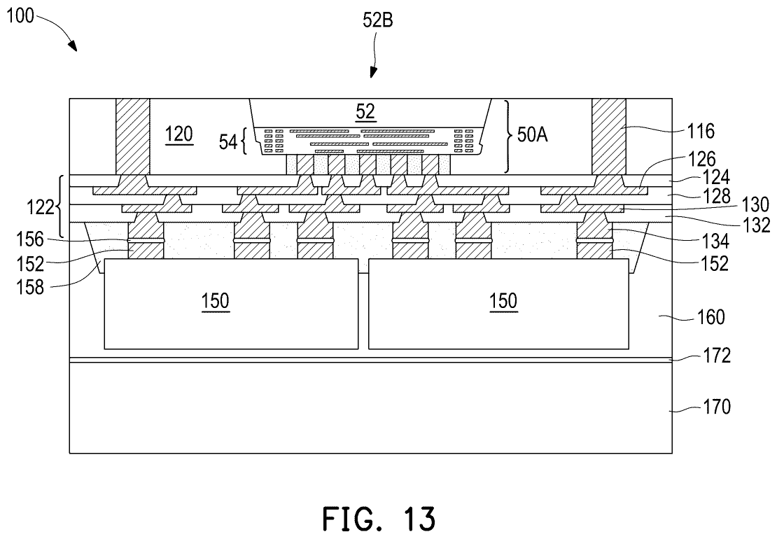

FIG. 13 illustrates the semiconductor package 100 after it has been separated from the second carrier substrate 170. The release layer 172 facilitates the separation process, allowing the completed semiconductor package 100 to be removed without damage to its components. The second carrier substrate 170 and the release layer 172 may be similar to the carrier substrate 102 and the release layer 104 described above and the descriptions are not repeated herein.

In FIG. 13, a planarization process is performed at the backside 52B of the semiconductor substrate 52, such as on the encapsulant 120 and the encapsulant 90, to expose the through vias 116 and potentially the semiconductor substrate 52. In some embodiments, a de-bonding process may be performed to detach the carrier substrate 102 before the planarization process. In some embodiments, the de-bonding process includes projecting a light such as a laser light or a UV light on the release layer 104 so that the release layer 104 decomposes and the carrier substrate 102 can be removed. In some embodiments, the de-bonding process is skipped, and the planarization process includes removing the carrier substrate 102 and the release layer 104. Whether the de-bonding process is performed, the planarization process may remove materials of the metallization pattern 110, the adhesive film 92, the through vias 116, and the semiconductor substrate 52 until the through vias 116 are sufficiently exposed. Top surfaces of through vias 116, encapsulant 120, and semiconductor substrate 52 are substantially coplanar after the planarization process within process variations. The planarization process may be, for example, a chemical-mechanical polish (CMP), a grinding process, or the like.

In some embodiments, through vias are included within the semiconductor substrate 52 (e.g., at or before the stage of FIGS. 1A-B) and they would be exposed by this planarization step.

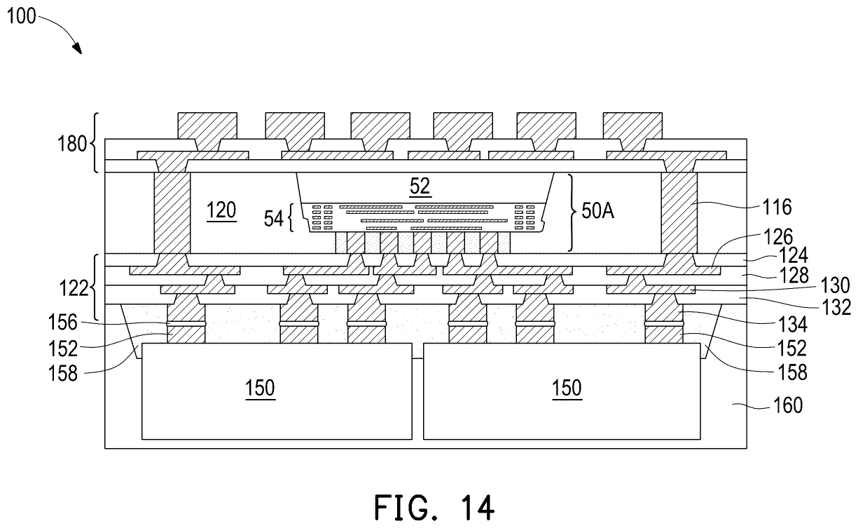

FIG. 14 illustrates the formation of a back-side redistribution structure 180. The back-side redistribution structure 180 may be formed on the opposite side of the interconnect die 50A from the front-side redistribution structure 122.

The back-side redistribution structure 180 may be similar in construction to the front-side redistribution structure 122. In some cases, the back-side redistribution structure 180 may include multiple layers of dielectric materials and conductive patterns. These layers may provide additional routing options for electrical connections within the semiconductor package 100.

The formation of the back-side redistribution structure 180 may involve several processing steps. In some cases, the semiconductor substrate 52 of the interconnect die 50A may be thinned to reduce the overall thickness of the semiconductor package 100. This thinning process may be performed using techniques such as grinding, chemical-mechanical polishing, or etching.

After thinning, the back-side redistribution structure 180 may be built up on the exposed backside 52B of the semiconductor substrate 52. The process may involve depositing alternating layers of dielectric materials and conductive patterns, similar to the formation of the front-side redistribution structure 122.

The back-side redistribution structure 180 may provide several benefits to the semiconductor package 100. In some cases, the back-side redistribution structure 180 may allow for additional electrical connections to be made to the interconnect die 50A, potentially increasing the overall functionality of the semiconductor package 100. The back-side redistribution structure 180 may also facilitate heat dissipation from the interconnect die 50A, potentially improving the thermal performance of the semiconductor package 100.

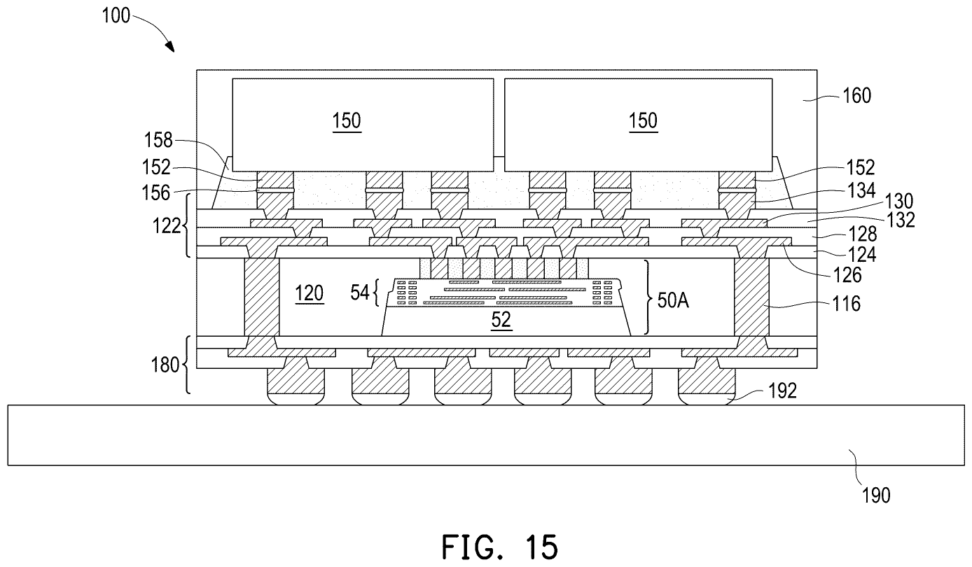

FIG. 15 illustrates a cross-sectional view of the completed semiconductor package 100 mounted on a substrate 190. The substrate 190 may serve as a platform for integrating the semiconductor package 100 into a larger electronic system.

The semiconductor package 100 may be electrically and mechanically connected to the substrate 190 through conductive connectors 192 (may also be referred to as conductive terminals 192). In some cases, the conductive connectors 192 may be solder balls, copper pillars, or other types of conductive structures. The conductive connectors 192 may provide electrical pathways between the semiconductor package 100 and the substrate 190, allowing for the transfer of signals and power.

The mounting process of the semiconductor package 100 on the substrate 190 may involve several steps. In some cases, the conductive connectors 192 may be formed on the back-side redistribution structure 180 of the semiconductor package 100. The semiconductor package 100 may then be aligned with corresponding connection points on the substrate 190. Heat may be applied to reflow the conductive connectors 192, creating secure electrical and mechanical connections between the semiconductor package 100 and the substrate 190. The conductive connectors 192 may providing an electrical connection for a ground or power supply voltage between the semiconductor package 100 and an external component, and the conductive connectors 192 and their respective parts of the back-side redistribution structure 180 may include solder regions and intermetallic compound (IMC) regions.

The completed semiconductor package 100 mounted on the substrate 190 may represent a fully functional electronic component ready for integration into a larger system. The combination of the front-side redistribution structure 122, the back-side redistribution structure 180, and the mounting on the substrate 190 may provide a high degree of flexibility in terms of electrical routing and system integration.

In some cases, the semiconductor package 100 may include additional components or features not explicitly shown in FIG. 15. For example, underfill materials may be used to further secure the semiconductor package 100 to the substrate 190 and provide additional protection against environmental factors.

The semiconductor package 100 with its dual redistribution structures and mounting capabilities may offer several advantages. The package may provide a high degree of integration, allowing for complex electronic systems to be built in a compact form factor. The use of both front-side and back-side redistribution structures may enable more flexible routing of electrical signals, potentially improving the overall performance of the electronic system.

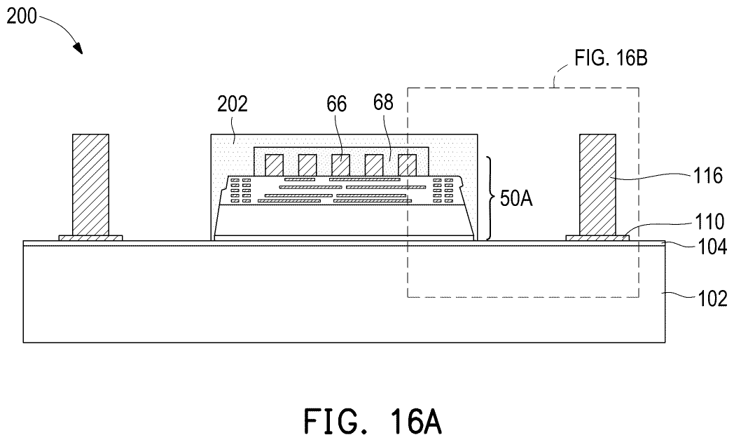

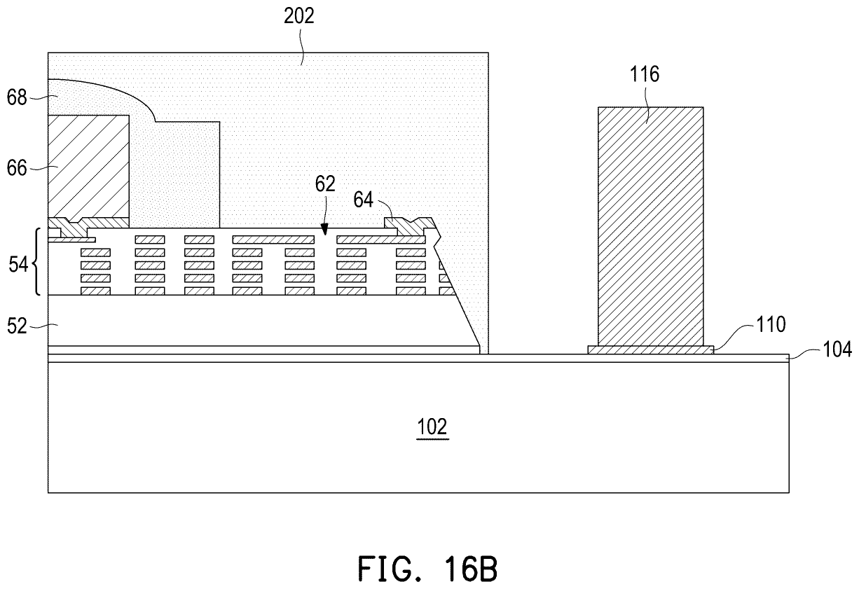

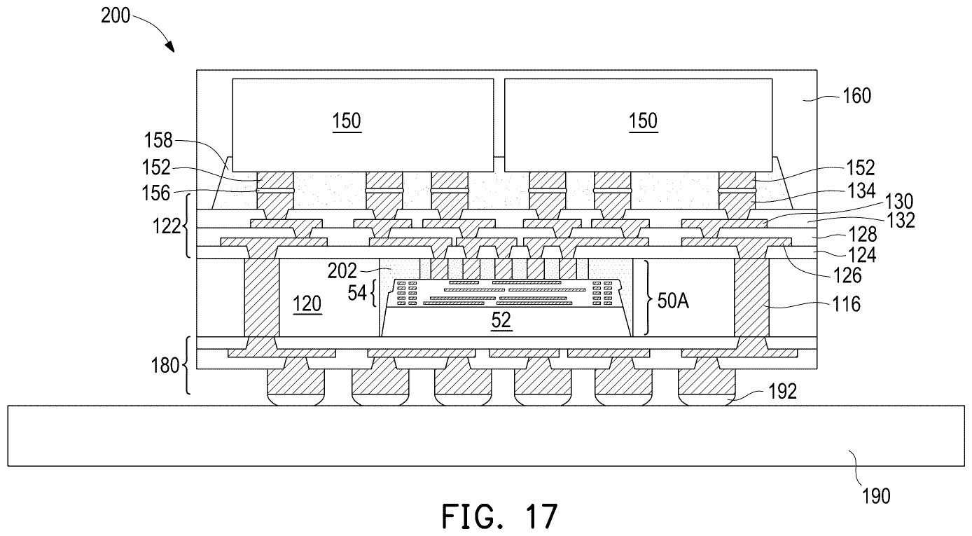

FIGS. 16A, 16B, and 17 illustrate cross-sectional views of intermediate stages in the manufacturing a semiconductor package 200, in accordance with some embodiments. This embodiment is similar to the semiconductor package 100 and further includes an insulating layer 202 over the interconnect die 50A. The details of the previous embodiments that are similar to this embodiment are not repeated herein. FIGS. 16A-B are a similar stage in processing as FIG. 7 described above and the description is not repeated herein.

In this embodiment, an insulating layer 202 is formed over the singulated interconnect die 50A. The insulating layer 202 may be formed over the alignment mark 62, providing additional protection and functionality.

In some embodiment, the insulating layer 202 may be a transparent layer. The transparency of the insulating layer 202 may allow the alignment mark 62 to be alignable through visible light. This feature may enhance the visibility and accuracy of the alignment process during subsequent manufacturing steps.

The insulating layer 202 may comprise a material selected from the group consisting of BCB, polyimide, and PBO. These materials may offer specific properties that benefit the semiconductor package 200, such as low dielectric constants, high thermal stability, or good adhesion characteristics.

FIG. 16B provides a more detailed cross-sectional view of the structure in FIG. 16A. The insulating layer 202 is formed over the interconnect die 50A, covering the alignment mark 62 and other components. In some cases, the insulating layer 202 may be formed by a lamination process. This process may allow for uniform coverage and good adhesion to the underlying structures.

FIG. 17 illustrates a cross-sectional view of the semiconductor package 200 at a later stage of assembly. The semiconductor package 200 includes the interconnect die 50A including the insulating layer 202. The processing steps from FIGS. 16A-B and FIG. 17 are similar to the steps 7 through 15 described above and the descriptions are not repeated herein.

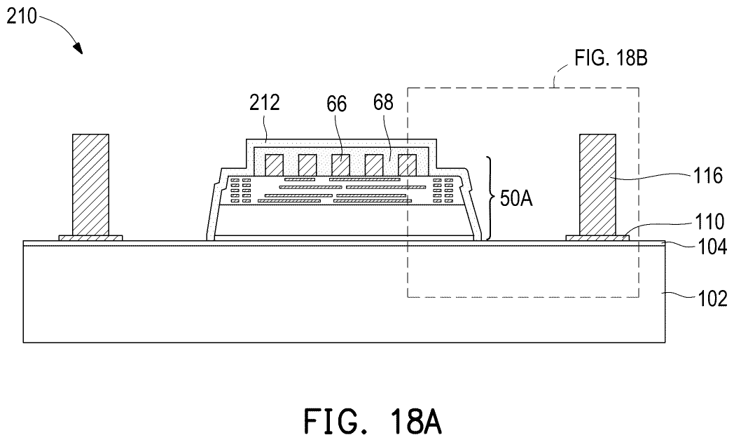

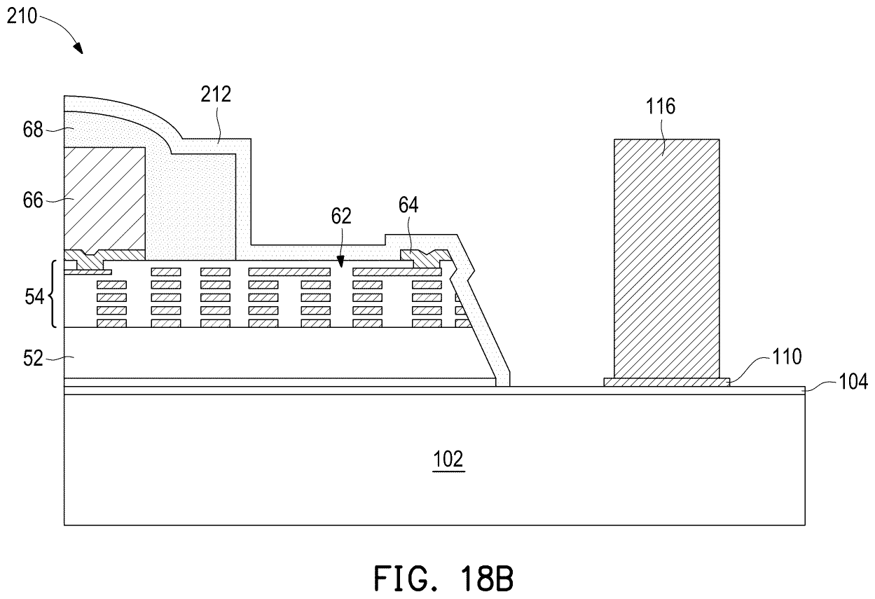

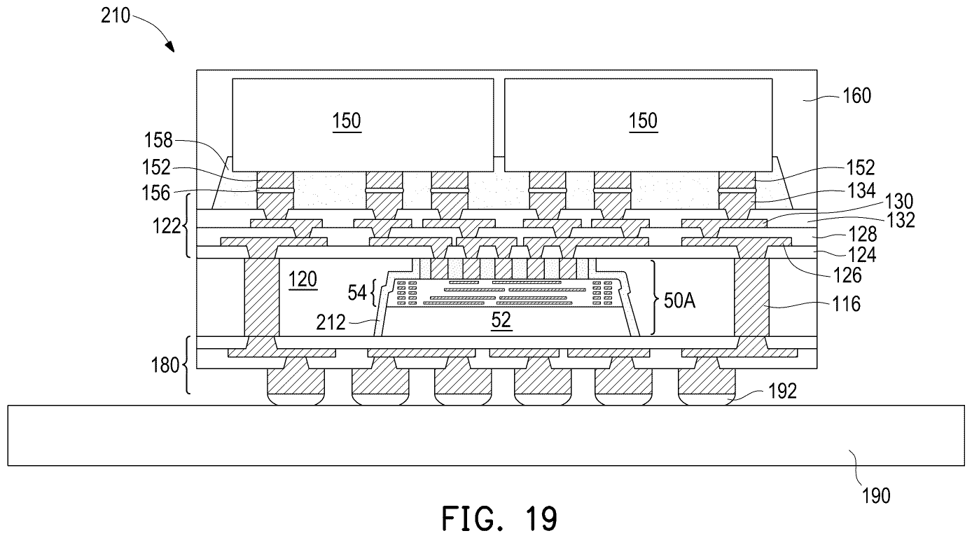

FIGS. 18A, 18B, and 19 illustrate cross-sectional views of intermediate stages in the manufacturing a semiconductor package 210, in accordance with some embodiments. This embodiment is similar to the semiconductor package 100 and further includes an insulating layer 212 over the interconnect die 50A. The details of the previous embodiments that are similar to this embodiment are not repeated herein. FIGS. 18A-B are a similar stage in processing as FIG. 7 described above and the description is not repeated herein.

In this embodiment, an insulating layer 212 is conformally formed over the interconnect die 50A, covering both the passivation layer 68 and the conductive features 66. The insulating layer 212 extends across the surface of the interconnect die 50A and provides protection for the underlying structures. In some cases, the insulating layer 212 may be formed by atomic layer deposition (ALD) or physical vapor deposition (PVD). These deposition techniques may allow for precise control of the insulating layer thickness and composition.

FIG. 18B provides a more detailed cross-sectional view of the semiconductor package 210. The insulating layer 212 is formed over portions of the structure, covering the alignment mark 62 and extending over adjacent areas. In some cases, the insulating layer 212 may include low oxygen permission material such as nitride, metal film, or adhesion promoter. These materials may provide additional protection against oxidation or other environmental factors.

FIG. 17 illustrates a cross-sectional view of the semiconductor package 210 at a later stage of assembly. The semiconductor package 210 includes the interconnect die 50A including the insulating layer 212. The processing steps from FIGS. 18A-B and FIG. 19 are similar to the steps 7 through 15 described above and the descriptions are not repeated herein.

The inclusion of the insulating layer 202 or 212 in these embodiments may provide several benefits. The insulating layer may offer additional protection for the alignment mark 62 and other sensitive components of the interconnect die 50A. This protection may help maintain the integrity and visibility of the alignment mark 62 throughout various manufacturing processes, potentially improving alignment accuracy in subsequent steps.

The conformal nature of the insulating layer 212 in some embodiments may provide uniform coverage across the interconnect die 50A surface. This uniform coverage may help distribute stress and protect against environmental factors such as moisture or contaminants.

The use of transparent materials for the insulating layer may allow for alignment processes that utilize visible light, potentially simplifying alignment procedures or enabling the use of certain types of alignment equipment. The selection of specific materials for the insulating layer, such as BCB, PI, or PBO, may allow for tailoring of the layer's properties to meet specific package requirements or performance goals.

By incorporating these embodiments with insulating layers, the semiconductor packages 200 and 210 may offer enhanced protection, improved alignment capabilities, and potentially greater flexibility in manufacturing processes. These features may contribute to the overall reliability and performance of the semiconductor packages in various applications.

The semiconductor package and manufacturing method described in this disclosure offer several advantages in the field of integrated circuit packaging. By exposing the alignment mark through an opening in the passivation layer and optionally covering it with a different insulation material, the accuracy and reliability of die alignment during package assembly are significantly improved. This approach addresses the issue of passivation layer damage during singulation, which can affect alignment mark visibility and lead to increased failure rates in package-on-package processes.

The disclosed method is compatible with existing semiconductor manufacturing processes, allowing for easy integration into current production lines without requiring substantial changes to established workflows or equipment. This compatibility ensures that the benefits of improved alignment can be realized without significant disruption to manufacturing operations.

The semiconductor package described herein offers enhanced flexibility in terms of electrical routing and system integration. The use of both front-side and back-side redistribution structures enables more complex interconnections within a compact form factor. This design approach allows for higher connection density and potentially improved overall system performance.

The encapsulation techniques and redistribution structures described in this disclosure contribute to the robustness and reliability of the semiconductor package. The encapsulant provides protection against environmental factors and mechanical stresses, while the redistribution structures offer flexibility in designing electrical connections for various applications.

The semiconductor package and manufacturing method described in this disclosure have potential applications in a wide range of electronic devices where compact size, high performance, and reliability are crucial. These may include smartphones, tablets, wearable devices, automotive electronics, and various Internet of Things (IoT) devices. The improved alignment accuracy and packaging flexibility offered by this approach could enable the development of more advanced and compact electronic systems in these and other fields.

In an embodiment, a method includes forming an interconnect structure including a plurality of die regions separated by scribe lines, at least one die region of the plurality of die regions including a semiconductor substrate and a routing structure on the semiconductor substrate, the routing structure including an alignment mark, the alignment mark being adjacent to the scribe lines, forming a passivation layer over the routing structure, removing a portion of the passivation layer to expose the alignment mark, and performing a singulation process to separate the interconnect structure into individual dies.

The described embodiments may also include one or more of the following features. The method further includes mounting one of the individual dies on a carrier substrate, forming an encapsulant laterally encapsulating the individual die and extending over the exposed alignment mark, and forming a redistribution structure over the encapsulant, where the redistribution structure is electrically connected to the routing structure. The method further includes mounting an integrated circuit device on and electrically coupled to the redistribution structure, and dispensing an underfill between the integrated circuit device and the redistribution structure. The method further includes forming an insulation layer over the exposed alignment mark before forming the encapsulant, the insulation layer including a material different from the passivation layer. The insulation layer includes a material selected from the group consisting of benzocyclobutene (BCB), polyimide (PI), and polybenzoxazole (PBO). Removing the portion of the passivation layer includes performing a photolithography process to form an opening having an octagonal shape in a plan view. Performing the singulation process includes laser grooving and blade sawing.

In an embodiment, a method includes forming a passivation layer over a routing structure of a die, the routing structure being on a semiconductor substrate, the routing structure including multiple conductive layers and multiple dielectric layers, an alignment mark, and a seal ring structure, removing a portion of the passivation layer to form an opening exposing the alignment mark, the opening having an octagonal shape in a plan view, after exposing the alignment mark, forming an encapsulant laterally encapsulating the die and extending over the alignment mark, and forming a redistribution structure over the encapsulant, the redistribution structure being electrically connected to the routing structure, the redistribution structure including a conductive line and a conductive via, where the conductive line and the conductive via include an adhesion layer and a copper-containing conductive layer over the adhesion layer, and where the conductive line acts as a signal line, a power routing line, or a ground routing line.

The described embodiments may also include one or more of the following features. The method further includes forming an insulation layer over the alignment mark, the insulation layer including a material different from the passivation layer, the insulation layer being a conformal layer. The insulation layer includes a material selected from the group consisting of benzocyclobutene (BCB), polyimide (PI), and polybenzoxazole (PBO). The method further includes mounting an integrated circuit device on the redistribution structure, where the integrated circuit device is electrically connected to the redistribution structure. The method further includes forming conductive connectors electrically coupling the integrated circuit device and the redistribution structure, and dispensing an underfill between the integrated circuit device and the redistribution structure, where the underfill surrounds the conductive connectors. Removing the portion of the passivation layer includes performing a photolithography process to pattern and etch the passivation layer.

In an embodiment, a semiconductor package includes an interconnect die including a semiconductor substrate having a first side and a second side opposite to the first side, a routing structure on the first side of the semiconductor substrate, the routing structure including a plurality of metallization layers disposed in a plurality of dielectric layers, the routing structure including a die area, a seal ring structure, and an alignment mark, the seal ring structure including wall-like metal features surrounding the die area of the routing structure, die connectors on the die area of the routing structure, and a passivation layer laterally surrounding the die connectors, the alignment mark being laterally spaced apart from the passivation layer, and an encapsulant extending along sidewalls of the interconnect die, the encapsulant extending over the alignment mark, a footprint of the encapsulant being greater than a footprint of the interconnect die in a plan view.

The described embodiments may also include one or more of the following features. The semiconductor package further includes an insulation layer laterally surrounding the passivation layer and on sidewalls of the interconnect die, the insulating layer covering the alignment mark. The insulation layer has a different material composition than the passivation layer. The insulation layer is a conformal layer over the alignment mark and on sidewalls of the interconnect die. The semiconductor package further includes a redistribution structure over the encapsulant and electrically connected to the routing structure, and an integrated circuit device on and electrically connected to the redistribution structure. The semiconductor package further includes conductive connectors electrically coupling the integrated circuit device to the redistribution structure, and an underfill between the integrated circuit device and the redistribution structure, the underfill surrounding the conductive connectors. The interconnect die includes non-planar sidewalls having different slopes between a top portion and a bottom portion of the sidewalls.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
forming an interconnect structure comprising a plurality of die regions separated by scribe lines, at least one die region of the plurality of die regions comprising a semiconductor substrate and a routing structure on the semiconductor substrate, the routing structure including an alignment mark, the alignment mark being adjacent to the scribe lines;
forming a passivation layer over the routing structure;
removing a portion of the passivation layer to expose the alignment mark; and
performing a singulation process to separate the interconnect structure into individual dies.

2. The method of claim 1, further comprising:
mounting one of the individual dies on a carrier substrate; and
forming an encapsulant laterally encapsulating the individual die and extending over the exposed alignment mark; and
forming a redistribution structure over the encapsulant, wherein the redistribution structure is electrically connected to the routing structure.

3. The method of claim 2, further comprising:
mounting an integrated circuit device on and electrically coupled to the redistribution structure; and
dispensing an underfill between the integrated circuit device and the redistribution structure.

4. The method of claim 2, further comprising:
forming an insulation layer over the exposed alignment mark before forming the encapsulant, the insulation layer comprising a material different from the passivation layer.

5. The method of claim 4, wherein the insulation layer comprises a material selected from the group consisting of benzocyclobutene (BCB), polyimide (PI), and polybenzoxazole (PBO).

6. The method of claim 1, wherein removing the portion of the passivation layer comprises performing a photolithography process to form an opening having slanted corners in a plan view.

7. The method of claim 1, wherein performing the singulation process comprises laser grooving and blade sawing.

8. A method, comprising:
forming a passivation layer over a routing structure of a die, the routing structure being on a semiconductor substrate, the routing structure comprising multiple conductive layers and multiple dielectric layers, an alignment mark, and a seal ring structure;
removing a portion of the passivation layer to form an opening exposing the alignment mark in a plan view;
after exposing the alignment mark, forming an encapsulant laterally encapsulating the die and extending over the alignment mark; and
forming a redistribution structure over the encapsulant, the redistribution structure being electrically connected to the routing structure, the redistribution structure comprising a conductive line and a conductive via, wherein the conductive line and the conductive via comprise a copper-containing conductive layer, and wherein the conductive line acts as a signal line, a power routing line, or a ground routing line.

9. The method of claim 8, further comprising:
forming an insulation layer over the alignment mark, the insulation layer comprising a material different from the passivation layer, the insulation layer being a conformal layer.

10. The method of claim 9, wherein the insulation layer comprises a material selected from the group consisting of benzocyclobutene (BCB), polyimide (PI), and polybenzoxazole (PBO).

11. The method of claim 8, further comprising:
mounting an integrated circuit device on the redistribution structure, wherein the integrated circuit device is electrically connected to the redistribution structure.

12. The method of claim 11, further comprising:
forming conductive connectors electrically coupling the integrated circuit device and the redistribution structure; and
dispensing an underfill between the integrated circuit device and the redistribution structure, wherein the underfill surrounds the conductive connectors.

13. The method of claim 8, wherein removing the portion of the passivation layer comprises performing a photolithography process to pattern and etch the passivation layer, and wherein the passivation layer has an octagonal shape in the plan view after forming the opening.

14. A semiconductor package, comprising:
an interconnect die comprising:
a semiconductor substrate having a first side and a second side opposite to the first side;
a routing structure on the first side of the semiconductor substrate, the routing structure comprising a plurality of metallization layers disposed in a plurality of dielectric layers, at least one of the metal layers including a barrier layer interfacing one of the plurality of dielectric layers and a fill metal spaced apart from the one of the plurality of dielectric layers by the barrier layer, wherein an electrical conductivity of the barrier layer is less than an electrical conductivity of the fill metal, the routing structure comprising a die area, a seal ring structure, and an alignment mark, the seal ring structure comprising wall-like metal features surrounding the die area of the routing structure, the seal ring structure comprising a material including copper at an atomic percentage greater than 80%;
die connectors on the die area of the routing structure; and
a passivation layer laterally surrounding the die connectors, the alignment mark being laterally spaced apart from the passivation layer; and
an encapsulant extending along sidewalls of the interconnect die, a footprint of the encapsulant being greater than a footprint of the interconnect die in a plan view.

15. The semiconductor package of claim 14, further comprising:
an insulation layer laterally surrounding the passivation layer and on sidewalls of the interconnect die, the insulating layer covering the alignment mark.

16. The semiconductor package of claim 15, wherein the insulation layer has a different material composition than the passivation layer.

17. The semiconductor package of claim 15, wherein the insulation layer is a conformal layer over the alignment mark and on sidewalls of the interconnect die.

18. The semiconductor package of claim 14, further comprising:
a redistribution structure over the encapsulant and electrically connected to the routing structure; and
an integrated circuit device on and electrically connected to the redistribution structure.

19. The semiconductor package of claim 18, further comprising:
conductive connectors electrically coupling the integrated circuit device to the redistribution structure; and
an underfill between the integrated circuit device and the redistribution structure, the underfill surrounding the conductive connectors.

20. The semiconductor package of claim 14, wherein the substrate comprises non-planar sidewalls having different slopes between a top portion and a bottom portion of the sidewalls, and wherein the passivation layer comprises planar sidewalls.
